(19) United States
(12) Patent Application Publication
(10) Pub. No.: US 2011/0048518 A1
(43) Pub. Date: Mar. 3, 2011

(54) Nanostructured thin film inorganic solar cells

(75) Inventors: Shuqiang Yang, Austin, TX (US); Sidlgata V. Sreenivasan, Austin, TX (US); Frank Y. Xu, Round Rock, TX (US)

(73) Assignees: MOLECULAR IMPRINTS, INC., Austin, TX (US); BOARD OF REGENTS, THE UNIVERSITY OF TEXAS SYSTEM, Austin, TX (US)

(21) Appl. No.: 12/857,816

(22) Filed: Aug. 17, 2010

Related U.S. Application Data
(60) Provisional application No. 61/246,432, filed on Sep. 28, 2009.
(60) Provisional application No. 61/236,960, filed on Aug. 26, 2009.

(51) Int. Cl. H01L 31/0352; H01L 31/105; H01L 31/18

(52) U.S. Cl. 136/255; 136/256; 438/71; 257/E31.038; 257/E31.061

(57) ABSTRACT

Inorganic solar cells having a nano-patterned p-n or p-i-n junction to reduce electron and hole travel distance to the separation interface to be less than the magnitude of the drift length or diffusion length, and meanwhile to maintain adequate active material to absorb photons. Formation of the inorganic solar cells may include one or more nano-lithography steps.

### CROSS-REFERENCE TO RELATED APPLICATIONS

The application claims the benefit under 35 U.S.C. §119(e)(1) of U.S. Provisional Application No. 61/236,960 filed on Aug. 26, 2009, and No. 61/246,432 filed on Sep. 28, 2009, which are hereby incorporated by reference in their entirety.

### BACKGROUND INFORMATION

Photovoltaic cells generally provide electrical energy in exchange for light energy. This energy conversion results from absorption of photons providing electron-hole pairs. Providing p-type silicon material in contact with n-type silicon (e.g., p-n junction) provides diffusion of electrons from a region of high electron concentration (n-type silicon) to the region of low electron concentration (p-type silicon). As electrons diffuse across the p-n junction, they combine with holes in the p-type silicon creating an electric field. Photogenerated electron-hole pairs are separated by this electric field. Specifically, minority carrier-electrons in the p-type region diffuse to the n-type region, and vice versa resulting in an external circuit, i.e. the illuminated solar cell acts like a battery or an energy source.

Described herein are methods of forming photovoltaic cells using nano-fabrication methods. Nano-fabrication includes the fabrication of very small structures that have features on the order of 1000 nanometers or smaller. One application in which nano-fabrication has had a sizeable impact is in the processing of integrated circuits. The semiconductor processing industry continues to strive for larger production yields while increasing the circuits per unit area formed on a substrate; therefore, nano-fabrication becomes increasingly important. Nano-fabrication provides greater process control while allowing continued reduction of the minimum feature dimensions of the structures formed. Other areas of development in which nano-fabrication has been employed include solar cell technology, biotechnology, optical technology, mechanical systems, and the like. For example, nano-fabrication has been employed in organic solar cells in U.S. Ser. No. 12/324,120, which is hereby incorporated by reference in its entirety.

An exemplary nano-fabrication technique in use today is commonly referred to as imprint lithography. Exemplary imprint lithography processes are described in detail in numerous publications, such as U.S. Patent Publication No. 2004/0065976, U.S. Patent Publication No. 2004/0065252, and U.S. Pat. No. 6,936,194, all of which are hereby incorporated by reference.

An imprint lithography technique disclosed in each of the aforementioned U.S. patent publications and patent includes formation of a relief pattern in a formable layer and transferring a pattern corresponding to the relief pattern into an underlying substrate. The substrate may be coupled to a motion stage to obtain a desired positioning to facilitate the patterning process. The patterning process uses a template spaced apart from the substrate and a formable liquid applied between the template and the substrate. The formable liquid is solidified to form a rigid layer that has a pattern conforming to a shape of the surface of the template that contacts the formable liquid. After solidification, the template is separated from the rigid layer such that the template and the substrate are spaced apart. The substrate and the solidified layer are then subjected to additional processes to transfer a relief image into the substrate that corresponds to the pattern in the solidified layer.

### BRIEF DESCRIPTION OF DRAWINGS

So that the present invention may be understood in more detail, a description of embodiments of the invention is provided with reference to the embodiments illustrated in the appended drawings. It is to be noted, however, that the appended drawings illustrate only typical embodiments of the invention, and are therefore not to be considered limiting of the scope.

FIG. 1 illustrates a simplified side view of an exemplary prior art thin-film solar cell.

FIG. 2 illustrates a simplified side view of an exemplary solar cell design in accordance with an embodiment of the present invention.

FIG. 3 illustrates a simplified side view of another exemplary solar cell design.

FIGS. 4-6 illustrate top-down views of the solar cells illustrated in FIGS. 2-3 along line X and Y.

FIG. 7 illustrates another exemplary solar cell design.

FIG. 8 illustrates another exemplary solar cell design.

FIG. 9 illustrates another exemplary solar cell design.

FIGS. 10-17 illustrate an exemplary method of forming the solar cell illustrated in FIG. 2.

FIG. 18 illustrates a simplified side view of a lithographic system in accordance with an embodiment of the present invention.

FIGS. 19-29 illustrate an exemplary method of forming the solar cell design in FIG. 8.

### DETAILED DESCRIPTION

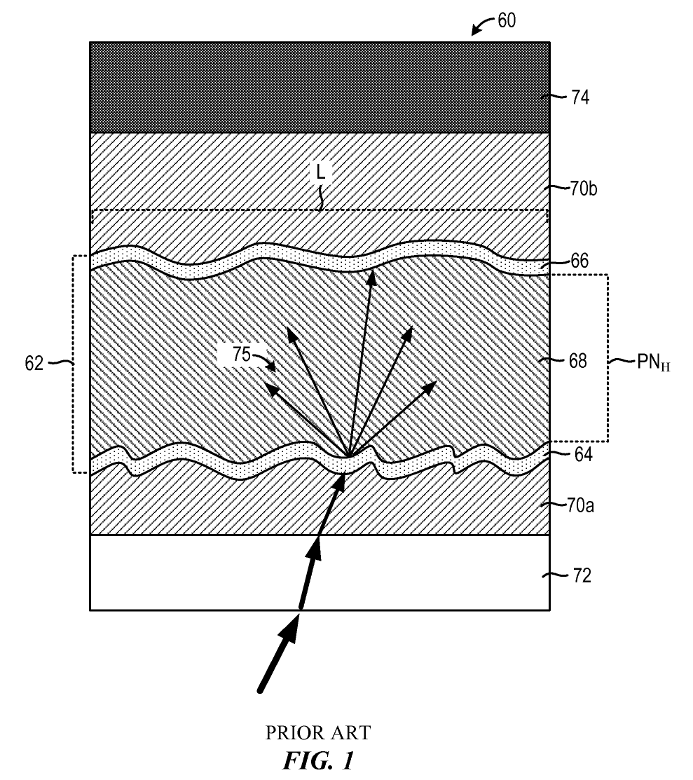

Thin-film silicon solar cells 60, as illustrated in FIG. 1, generally require far lower amounts of silicon material than “wafer based” crystalline solar cells known within the art. Currently, thin-film silicon solar cells 60 are formed using plasma-enhanced chemical vapor deposition (PECVD) and based on a p-i-n structure 62. The p-i-n structure 62 includes a p-type material layer 64 and an n-type material layer 66 having an intrinsic silicon film 68 positioned therebetween. P-type material layer 64 may have a thickness t₁, n-type material layer 66 may have a thickness t₂, and intrinsic silicon film 68 may have a thickness t₃. The excitons (electron/hole pairs) created in the intrinsic layer by incident photons may possess a drift length and a diffusion length L (i.e., the average length an electron or hole travels before recombining (e.g. approximately 100-300 nm)).

The p-i-n structure 62 may be positioned between electrodes 70a and 70b. Electrodes 70a and 70b, for example, may be transparent (e.g., ZnO). Additionally, a substrate layer 72 (e.g., glass) and a back reflector 74 may be positioned adjacent to electrodes 70a and 70b respectively.

Within the p-i-n structure 62, a built-in-field 75 may be created in the intrinsic silicon film 68. Field 75 may aid in guiding charges to the appropriate electrode 70 depending on design considerations.

Depending on deposition conditions, intrinsic film 68 may be amorphous (a-Si:H) or microcrystalline (μc-Si:H). See A. V. Shah et al., “Thin-film Silicon Solar Cell Technology,” Prog. Photovolt: Res. Appl. 2004; 12:113-142, which is hereby incorporated by reference in its entirety. While thin-film silicon solar cells, such as the one depicted in FIG. 1, may be cost effective, have relatively low efficiency, and/or low deposition rates. As such, formation may include long lag times in order to deposit even 1 μm films.

Further, thin-film silicon solar cells, similar to solar cell 60, may only achieve efficiency values of approximately 10%. For production modules, this efficiency may be even further reduced based on numerous practical reduction factors. Therefore, the current practical efficiency values may be only approximately 6-8%.

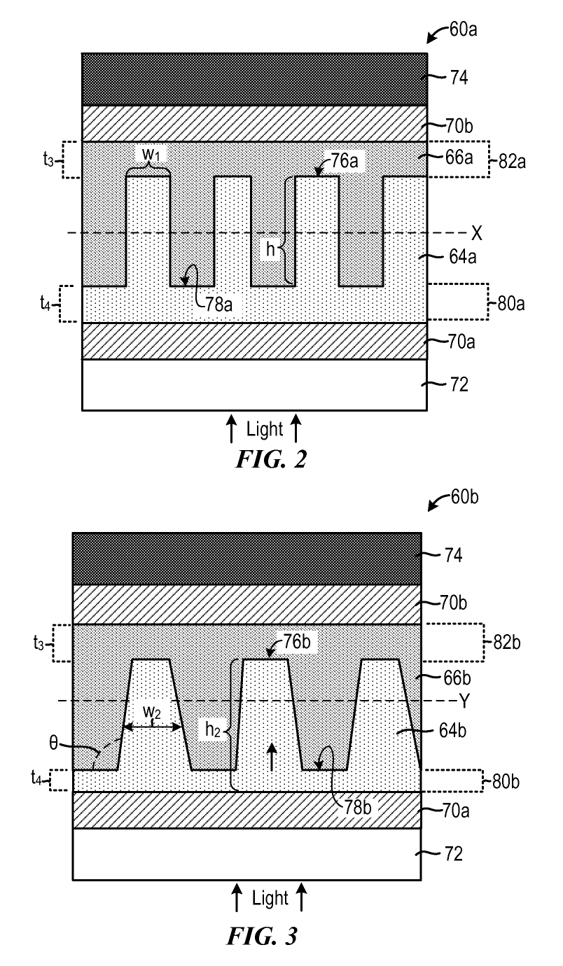

FIGS. 2-9 provide multiple embodiments of solar cells 60a-60e in accordance with the present invention. Solar cells 60a-60e may include a nano-patterned p-n or p-i-n junction. The purpose of the patterning is to reduce electron and hole (created by incident photos) maximum travel distance d₁ that is less than the magnitude of the diffusion length L and/or drift length, and meanwhile to maintain adequate active material to absorb photos. Generally, solar cells 60a-60e include one or more protrusions 76. Protrusions 76 may be formed using one or more nano-imprint lithography steps. By incorporating nano-imprint lithography steps in formation of solar cells 60a-60e, efficiency may be significantly increased as compared to the prior art without a major negative impact on cost.

Solar cells 60a-60e may include materials known in the art capable of forming thin-film silicon solar cells. Alternatively, one or more of solar cells 60a-60e designs may be formed of other solar thin-film materials. For example, design of solar cells 60c-60d may be used to provide CdTe solar cells and/or design of solar cells 60a-60e may be used to provide CuInGaSe solar cells. Design of solar cells 60a-60e may also increase efficiency of solar cells formed of other materials, such as Cu₂O, CuInS, FeS₂, and the like, generally known to posses relatively low efficiency.

FIG. 2 illustrates one embodiment of thin-film solar cell 60a having p-type material layer 64a with protrusions 76a and recessions 78a. P-type material layer 64a may include a base layer 80 with a thickness t₄ (e.g., approximately 100 nm or larger). Protrusions 76a may be adjacent to base layer 80a and have a height h (e.g., greater than approximately 100 nm). N-type material layer 66a may fill recessions 78a of p-type material layer 64a and include base layer 82a with a thickness t₃ (e.g., approximately 100 nm or larger). In one embodiment, protrusions 76a may be formed by etching. For example, protrusions 76a may be formed by etching Silicon using common Silicon etchants including, but not limited to, CF₄, CHF₃, SF₆, Cl₂, HBr, other Fluorine, Chlorine and Bromine based etchants, and/or the like. Additionally, protrusions 76a may be etched using an imprint resist as a mask, a hardmask for pattern transfer, or the like. For example, protrusions 76a may be etched using a hardmask formed of materials including, but not limited to, Cr, Silicon Oxide, Silicon Nitride, and/or the like. Note that this structure may be inverted, i.e. layer 64a is n-type and layer 66a is p-type. The working principle is similar.

FIG. 3 illustrates another embodiment of solar cell 60b similar to solar cell 60a with protrusions 76b of p-type material layer 64b including a variable width w₂. For example, width w₂ of protrusion 76b may have a magnitude that varies to provide a non-vertical wall angle Θ. Non-vertical wall angle Θ may assist in deposition of n-type material 66b and/or intrinsic material (not shown) by providing a sloped edge as compared to a vertical edge.

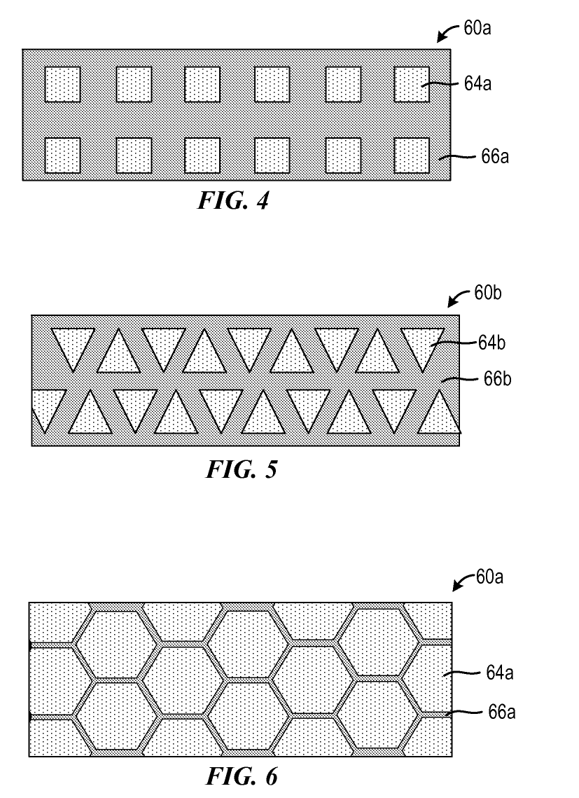

Shape of protrusions 76a and/or 76b in solar cells 60a and 60b respectively may include different shapes and/or different spacing between protrusions 76a and/or 76b. FIGS. 4-6 illustrate top-down views of solar cells 60a and 60b having exemplary shapes and sizes for protrusions 76a and/or 76b along lines X and Y respectively. Protrusions 76a and/or 76b may be circle, square, rectangular, triangular, polygonal, or any other fanciful shape. Additionally, spacing between protrusions 76a and/or 76b may be increased or decreased, uniform or sporadic, based on design considerations. Exemplary formation of nanoshapes is further described in U.S. Ser. No. 12/616,896, which is hereby incorporated by reference in its entirety.

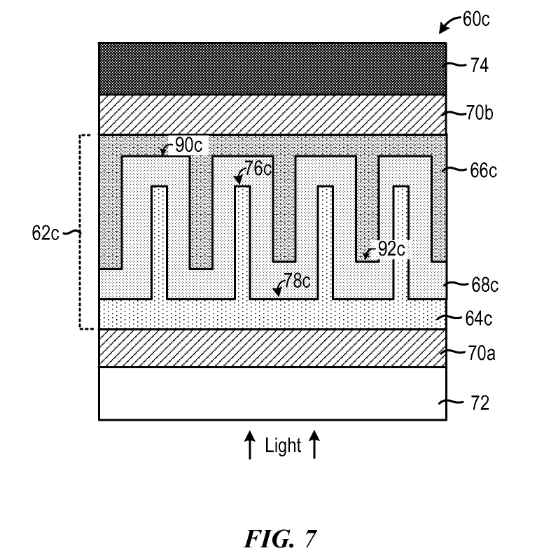

FIG. 7 illustrates another exemplary solar cell 60c. Solar cell 60c includes a p-i-n structure 62c. Intrinsic layer 68c may be formed between p-type material layer 64c and n-type material layer 66c. Intrinsic layer 68c may form a conformal or directional layer over protrusions 76c and/or recessions 78c of p-type material layer 64c. As such, intrinsic layer 68c may conform and thus include one or more protrusions 90c and recessions 92c.

Formation of solar cell 60c may include multiple nanopatterning step to form protrusions 76c and recessions 78c of p-type material layer 64c and/or protrusions 90c and 92c of intrinsic layer 68c. For example, formation of p-type material layer 64c may be through the use of a first nanopatterning step to form protrusions 76c and 78c. Material of intrinsic layer 68c may be deposited (e.g., directional deposition, conformal deposition or partial conformal deposition) on p-type material layer 64c to form protrusions 90c and recessions 92c. N-type layer 66c may be deposited on top of 68c. Note layer 66c may not fill all the recessions completely (some voids left due to deposition techniques).

It should be noted that protrusions 76c of p-type material layer 64c and protrusions 90c of intrinsic layer 68c may include a variable width w to provide a non-vertical wall angle Θ as described herein and illustrated in FIG. 3.

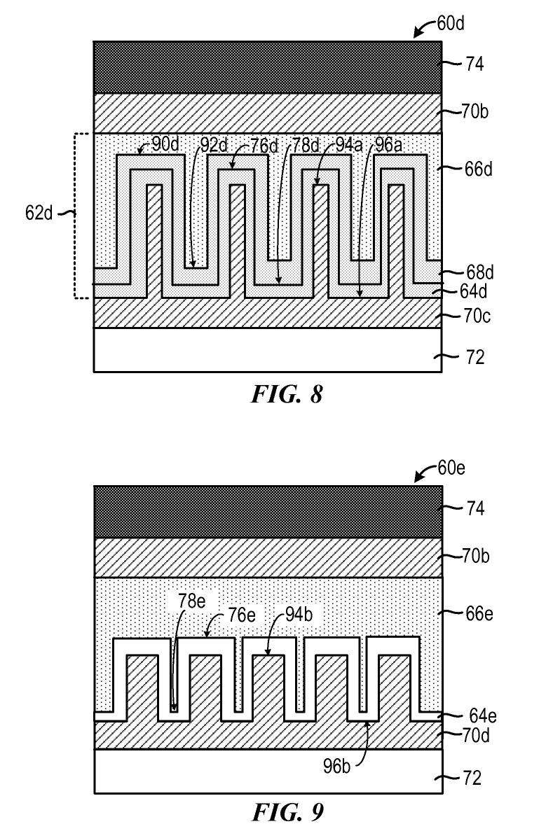

FIG. 8 illustrates another exemplary solar cell 60d. Solar cell 60d includes a p-i-n structure 62d. Additionally, solar cell 60d includes an electrode layer 70c having one or more protrusions 94a and recessions 96a. In one embodiment, protrusions 94a and recessions 96a may be formed by etching. For example, protrusions 94a may be formed by metal etchants including, but not limited to, Cl₂, BCl₃, other Chlorine based etchants, and/or the like. It should be noted that the metal etchants are not limited to chlorine-based etchants. For example, some metals, such as Tungsten, may be etched using Fluorine based etchants. Protrusions 94a may be formed by etching using an imprinting resist as a mask or by using a hardmask for pattern transfer. For example, protrusions 95a may be formed by using a hardmask formed of materials including, but not limited to, Cr, Silicon Oxide, Silicon Nitride, and/or the like.

P-type material layer 64d may be deposited on protrusions 94a and recessions 96a or electrode layer 70c form protrusions 76d and recessions 78d. Intrinsic layer 68d may be deposited on p-type material layer 64d form protrusions 90d and 92d. N-type material layer 66d may then be deposited on intrinsic layer 68d forming p-i-n structure 62d. Note layer 66d may not fill all the recessions completely (some voids left due to deposition techniques).

FIG. 9 illustrates another exemplary solar cell 60e. Solar cell 60e includes electrode layer 70d having one or more protrusions 94b and recessions 96b. Similar to electrode layer 70c of FIG. 8, electrode layer 70d may include protrusions 94b. In one embodiment, protrusions may be formed by etching. For example, protrusions 94b may be formed by metal etchants including, but not limited to, Cl₂, BCl₃, other Chlorine based etchants, and/or the like. It should be noted that the metal etchants are not limited to chlorine-based etchants. For example, some metals, such as Tungsten, may be etched using Fluorine based etchants. Protrusions 94b may be formed by etching using an imprinting resist as a mask or by using a hardmask for pattern transfer. For example, protrusions 94b may be formed by using a hardmask formed of materials including, but not limited to, Cr, Silicon Oxide, Silicon Nitride, and/or the like.

P-type material layer 64e may be deposited (e.g., directional deposition or conformal deposition or partical conformal deposition) on electrode layer 70d and/or formed by using a nano-lithography step to form protrusions 76e and recession 78e. N-type material layer 66e may be deposited (e.g., directional deposition or conformal deposition or partical conformal deposition) on p-type material layer 64e. Note that this structure may be inverted, i.e. layer 64e is n-type and layer 66e is p-type. The working principle is similar.

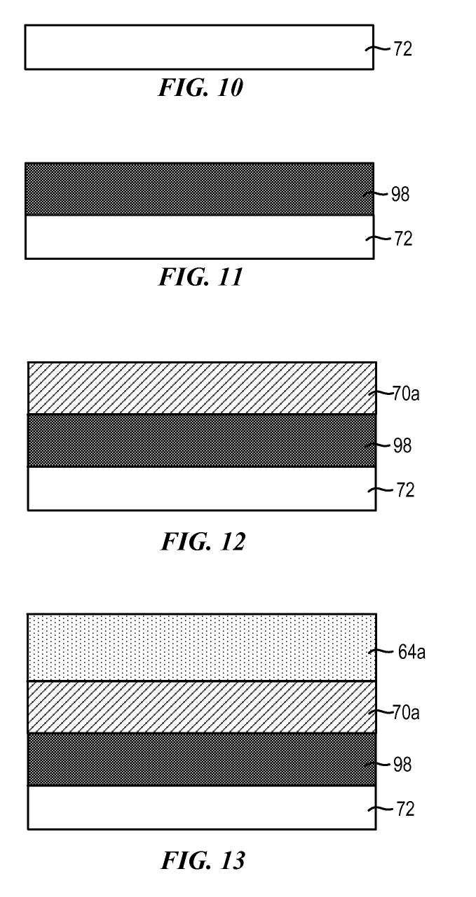

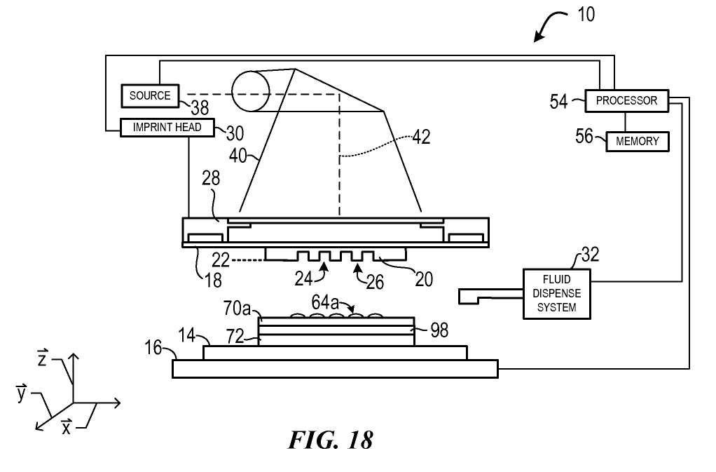

FIGS. 10-17 illustrate an exemplary method for forming solar cells (similar to 60a illustrated in FIG. 2, but with an inverted structure) using a lithography system 10 illustrated in FIG. 18. It should be noted that steps described herein may be modified to provide solar cells 60b-60e as described above (e.g., incorporating one or more nanolithography steps of one or more layers). For example, in one embodiment, steps described herein may be modified to provide p-i-n structure 62c of FIG. 7 that includes intrinsic layer 68c. In another embodiment, steps described herein may be modified to provide protrusions 94b of electrode layer 70d.

Referring to FIGS. 10 and 11, a metal contact/reflector layer 98 may optionally be deposited on substrate layer 72. Metal contact layer/reflector layer 98 may be formed of materials including, but not limited to, aluminum, tungsten, zinc, and/or the like. Electrode layer 70a (e.g., ZnO, Al, and the like) may be deposited (e.g., sputter) on reflector layer 98 as illustrated in FIG. 12. It should be noted that electrode layer 70a may be patterned to provide one or more features (e.g., protrusions). For example, electrode layer 70a may be patterned to provide protrusions as illustrated in FIGS. 8 and 9.

P-type material layer 64a may be deposited on electrode layer 70a. P-type material layer 64a may be formed to provide protrusions 76a and recessions 78a. It should be noted that either p-type material layer 64a or n-type material layer 66a may be formed to provide protrusions and recessions; however, for simplicity of description only the p-type material layer 64a is described herein. P-type material may include, but is not limited to, amorphous silicon, copper indium gallium selenide, microcrystalline silicone, nanocrystalline silicon, and the like.

Formation of protrusions 76a and recessions 78a in p-type material layer 64a may be through imprint lithography, optical lithography, x-ray lithography, extreme ultraviolet lithography, scanning probe lithography, atomic force microscopic nanolithography, magnetolithography, and/or the like. For example, protrusions 76a and recessions 78a of p-type material layer 64a may be formed using a lithographic system 10 illustrated in FIG. 18.

Referring to FIG. 18, substrate layer 72 may be coupled to substrate chuck 14. As illustrated, substrate chuck 14 is a vacuum chuck. Substrate chuck 14, however, may be any chuck including, but not limited to, vacuum, pin-type, groove-type, electrostatic, electromagnetic, and/or the like. Exemplary chucks are described in U.S. Pat. No. 6,873,087, which is hereby incorporated by reference.

Substrate layer 72 and substrate chuck 14 may be further supported by stage 16. Stage 16 may provide motion along the x-, y-, and z-axes. Stage 16, substrate layer 72, and substrate chuck 14 may also be positioned on a base (not shown).

Spaced-apart from substrate layer 72 is a template 18. Template 18 may include a mesa 20 extending therefrom towards substrate layer 72, mesa 20 having a patterning surface 22 thereon. Further, mesa 20 may be referred to as mold 20. Alternatively, template 18 may be formed without mesa 20.

Template 18 and/or mold 20 may be formed from such materials including, but not limited to, fused-silica, quartz, silicon, organic polymers, siloxane polymers, borosilicate glass, fluorocarbon polymers, metal, hardened sapphire, and/or the like. As illustrated, patterning surface 22 comprises features defined by a plurality of spaced-apart recesses 24 and/or protrusions 26, though embodiments of the present invention are not limited to such configurations. Patterning surface 22 may define any original pattern that forms the basis of a pattern to be formed in p-type material layer 64a.

Template 18 may be coupled to chuck 28. Chuck 28 may be configured as, but not limited to, vacuum, pin-type, groove-type, electrostatic, electromagnetic, and/or other similar chuck types. Exemplary chucks are further described in U.S. Pat. No. 6,873,087, which is hereby incorporated by reference. Further, chuck 28 may be coupled to imprint head 30 such that chuck 28 and/or imprint head 30 may be configured to facilitate movement of template 18.

System 10 may further comprise a fluid dispense system 32. Fluid dispense system 32 may be used to deposit p-type material on electrode layer 70a. P-type material may be in fluid form. For example, p-type material may be a liquid positioned upon electrode layer 70a using techniques such as drop dispense, spin-coating, dip coating, chemical vapor deposition (CVD), physical vapor deposition (PVD), thin film deposition, thick film deposition, and/or the like. P-type material may be disposed upon electrode layer 70a before and/or after a desired volume is defined between mold 20 and electrode layer 70a depending on design considerations. Alternatively, p-type material may be a solid positioned adjacent to electrode layer 70a and etched.

System 10 may further comprise an energy source 38 coupled to direct energy 40 along path 42. Imprint head 30 and stage 16 may be configured to position template 18 and substrate layer 72 in superimposition with path 42. System 10 may be regulated by a processor 54 in communication with stage 16, imprint head 30, fluid dispense system 32, and/or source 38, and may operate on a computer readable program stored in memory 56.

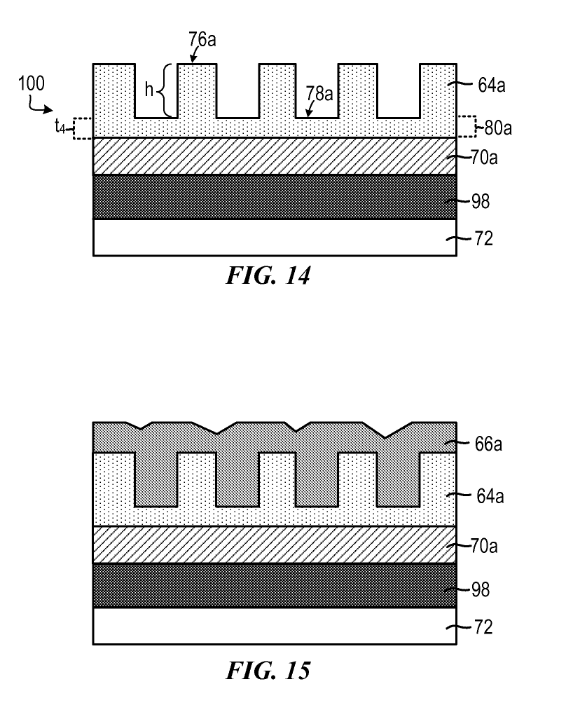

Referring to FIGS. 14 and 18, either imprint head 30, stage 16, or both may vary a distance between mold 20 and electrode layer 70a to define a desired volume therebetween that is filled by p-type material. For example, imprint head 30 may apply a force to template 18 such that mold 20 contacts p-type material. After the desired volume is filled with p-type material, source 38 produces energy 40, e.g., ultraviolet radiation, causing p-type material to solidify and/or cross-link conforming to shape of a surface 44 of electrode layer 70a and patterning surface 22, defining a patterned layer 100 on electrode layer 70a. Patterned layer 100 may comprise base layer 80a and a plurality protrusions 76a and recessions 78a, with protrusions 76a having height h and base layer 80a having a thickness t₄. It should be noted that solidification and/or cross-linking of p-type material may be through other methods including, but not limited, exposure to charged particles, temperature changes, evaporation, and/or other similar methods.

The above-mentioned system and process may be further employed using imprint lithography processes and systems referred to in U.S. Pat. No. 6,932,934, U.S. Patent Publication No. 2004/0124566, U.S. Patent Publication No. 2004/0188381, and U.S. Patent Publication No. 2004/0211754, each of which is hereby incorporated by reference in their entirety.

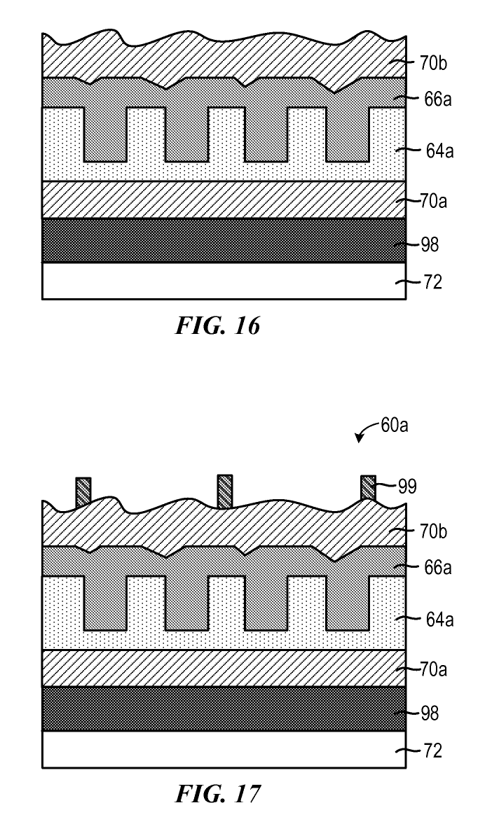

Referring to FIG. 15, n-type material layer 66a may be deposited on p-type material layer 64a filling recessions 78a of p-type material layer 64a. Electrode layer 70b (e.g., transparent conductor (ZnO, ITO, SnO2, etc.) may then be deposited on n-type material layer 66a as illustrated in FIG. 16. It should be noted that a conductive grid 99 may be deposited on electrode layer 70b as illustrated in FIG. 17. Conductive grid 99 may provide additional conductivity in addition to electrode layer 70b. For example, materiality of electrode layer 70b may be selected such that electrode layer 70b is substantially translucent; however, conductivity of electrode layer 70b may be compromised. Conductive grid 99 may provide the additional conductivity needed for solar cell 60a.

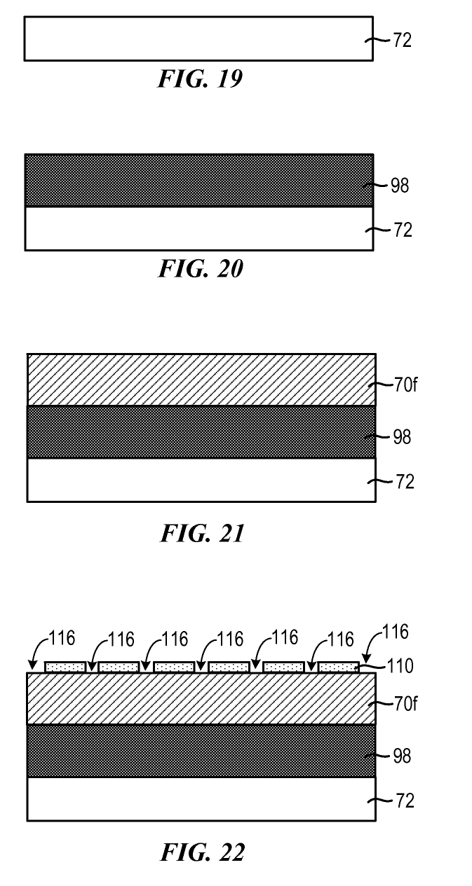

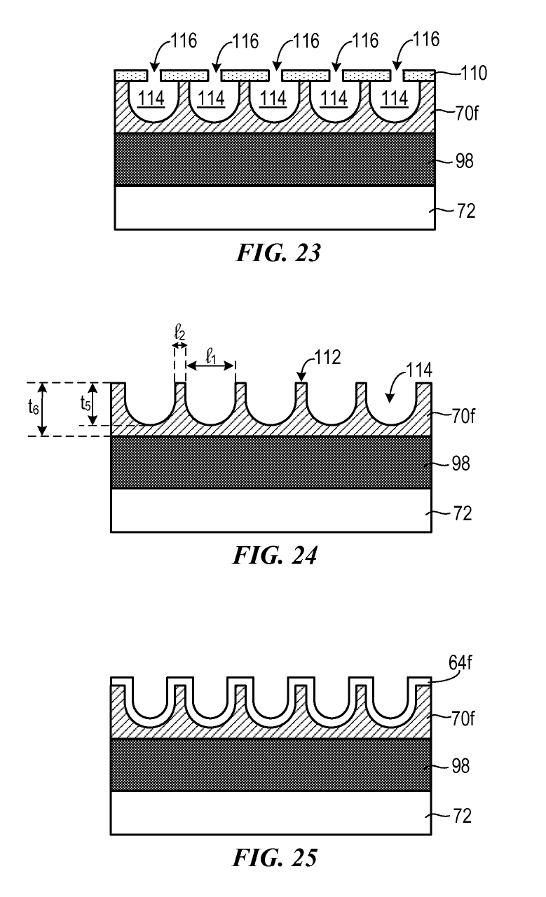

FIGS. 19-29 illustrate another exemplary method for forming solar cells 60f using a lithography system 10 illustrated in FIG. 18. It should be noted that steps described herein may be modified to provide solar cells 60b-60e as described above (e.g., incorporating one or more nanolithography steps of one or more layers).

Referring to FIGS. 19 and 20, a metal contact/reflector layer 98 may optionally be deposited on substrate layer 72. Metal contact layer/reflector layer 98 may be formed of materials including, but not limited to, aluminum, silver, tungsten, zinc, and/or the like.

Referring to FIGS. 21-24, an electrode layer 70f deposited on reflector layer 98 may be patterned to provide one or more features such as protrusions 112 and recessions 114.

Electrode layer 70f (e.g., ZnO, Al, and the like) may be deposited using techniques including, but not limited to chemical vapor deposition (CVD), physical vapor deposition (PVD), sputter deposition, spin-coating, dispensing of liquid, and the like. To form features 112 and 114 in electrode layer 70f, a material layer 110 may be deposited and/or patterned on electrode layer 70f such that gaps 116 expose portions of electrode layer 70f to etching chemistry.

Material layer 110 may be an organic monomer. For example, material layer 110 may include a monomer mixture as described in U.S. Pat. No. 7,157,036 and U.S. Patent Publication No. 2005/0187339, both of which are herein incorporated by reference.

In one example, material layer 110 may be formed having gaps 116 using imprint lithography processes and systems referred to in U.S. Pat. No. 6,932,934, U.S. Patent Publication No. 2004/0124566, U.S. Patent Publication No. 2004/0188381, and U.S. Patent Publication No. 2004/0211754, each of which is hereby incorporated by reference in their entirety. In another example, material layer 110 may be formed having gaps 116 using optical lithography, x-ray lithography, electron-beam lithography, and the like. Alternatively, polymerized material layer 110 may be deposited on electrode layer 70f such that gaps 116 are formed using techniques including, but not limited to, chemical vapor deposition (CVD), physical vapor deposition (PVD), sputter deposition, spin-coating, dispensing of liquid, and the like.

In one embodiment, gaps 116 in material layer 110 may be formed by a break through etch. For example, gaps 116 in material layer 110 may be formed using an oxygen-based reactive ion etching (RIE) process. Alternatively, gaps 116 in material layer 110 may be formed using VUV etching and/or UV ozone etching as described in U.S. Ser. No. 12/563,356 and U.S. Provisional No. 61/299,097, which are hereby incorporated by reference in their entirety.

Gaps 116 of material layer 110 may be sized and configured to provide expose portions of electrode layer 70f to etching chemistry to form protrusions 112 and recessions 114 as described herein. For example, gaps 116 of material layer 110 may be approximately 10-100 nm to expose electrode layer 70f to etching chemistry forming recessions 114 having a length L₁ of approximately 500 nm and protrusions 112 having a length L₂ of approximately 20 nm.

It should be noted that an adhesion layer (e.g., BT20) may be provided on material layer 110 and/or between material layer 110 and electrode layer 70f.

In one embodiment, electrode layer 70f may be formed of Al. To form protrusions 112 and recessions 114, etching chemistry may use a phosphoric acid, acetic acid, and/or other weak acids. Generally, weak acid may be used as strong oxidation acids (e.g., nitric acid) may oxidize material layer 110 causing delamination. Weak acids may be used alone or in combination with additives. For example, additives that etch electrode layer 70f (e.g., Al) without attacking organics. Alternatively, hydrogen fluoride (HF) containing a buffer oxide etch (BOE) solution may be used to etch electrode layer 70f forming protrusions 112 and recessions 114. This may minimally affect material layer 110 and/or adhesion layer.

Referring to FIG. 25, P-type material layer 64f may be deposited on electrode layer 70f filling a portion of recessions 114 of electrode layer 70f. P-type material may be provided in fluid form for the formation of p-type material layer 64f. For example, p-type material layer 64f may be provided on electrode layer 70f using techniques such as drop dispense, spin-coating, dip coating, chemical vapor deposition (CVD), physical vapor deposition (PVD), thin film deposition, thick film deposition, and/or the like. Alternatively, P-type material layer 64f may be provided in solidified form and adhered to electrode layer 70f.

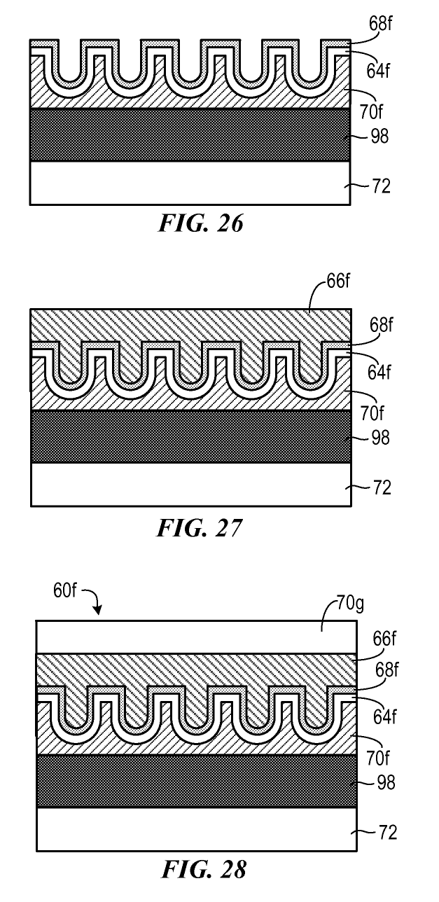

Referring to FIG. 26, intrinsic film 68f may be deposited on P-type material layer 64f. Intrinsic film 68f may be amorphous (a-Si:H) or microcrystalline (μc-Si:H). See A. V. Shah et al., “Thin-film Silicon Solar Cell Technology,” Prog. Photovolt: Res. Appl. 2004; 12:113-142, which is hereby incorporated by reference in its entirety. Deposition of intrinsic film 68f on P-type material layer 64f may depend on materiality of intrinsic film 68f. Intrinsic film 68f may be deposited on P-type material layer 64f using techniques such as drop dispense, spin-coating, dip coating, chemical vapor deposition (CVD), physical vapor deposition (PVD), thin film deposition, thick film deposition, and/or the like.

N-type material layer 66f may be deposited on intrinsic film 68f as illustrated in FIG. 27. Deposition of N-type material layer 66f on intrinsic film 68f may depend on materiality of N-type material layer 66f. For example, N-type material layer 66f may be deposited using techniques such as drop dispense, spin-coating, dip coating, chemical vapor deposition (CVD), physical vapor deposition (PVD), thin film deposition, thick film deposition, and/or the like. Electrode layer 70g (e.g., substantially translucent layer) may then be deposited on N-type material layer 66f as illustrated in FIG. 28.

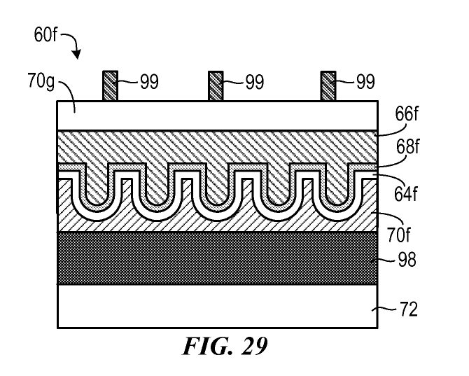

Referring to FIG. 29, it should be noted that a conductive grid 99 may be deposited on electrode layer 70g. Conductive grid 99 may provide additional conductivity in addition to electrode layer 70g. For example, materiality of electrode layer 70g may be selected such that electrode layer 70g is substantially translucent; however, conductivity of electrode layer 70g may be compromised. Conductive grid 99 may provide the additional conductivity needed for solar cell 60f. Note that this structure may be inverted, i.e. layer 64f is n-type and layer 66f is p-type. The working principle is similar.

What is claimed is:

1. An inorganic solar cell, comprising:
a patterned p-type material layer formed of inorganic semi-conducting material, the p-type material layer having a first set of protrusions and a first set of recessions;
an intrinsic layer positioned on the patterned p-type material layer, thickness of the intrinsic layer configured to be less than magnitude of diffusion length for the inorganic semi-conducting material; and,
an n-type material layer positioned on the intrinsic layer.

2. The inorganic solar cell of claim 1, wherein at least one protrusion includes a variable width providing a non-vertical wall angle.

3. The inorganic solar cell of claim 1, wherein shape of at least one protrusion is selected from a group consisting of circle, square, rectangle, triangle, and polygon.

4. The inorganic solar cell of claim 1, wherein thickness of the intrinsic layer is less than a magnitude of drift length for the solar cell.

5. The inorganic solar cell of claim 1, wherein the plurality of protrusions and the plurality of recessions of the p-type material layer are formed using an imprint lithography template.

6. The inorganic solar cell of claim 1, further comprising:
an electrode layer positioned adjacent to the p-type layer, the electrode layer having a second set of protrusions and a second set of recessions, wherein the p-type material layer forms a conformal layer on the electrode layer such that the first set of protrusions and the first set of recessions are formed.

7. The inorganic solar cell of claim 6, wherein at least one protrusion of the second set of protrusions is formed having a variable width providing a non-vertical wall angle.

8. The inorganic solar cell of claim 6, wherein shape of at least one protrusion of the second set of protrusions is selected from a group consisting of circle, square, rectangle, triangle, and polygon

9. The inorganic solar cell of claim 6, wherein the plurality of protrusions and the plurality of recessions are formed by a metal etchant using an imprinting resist as a mask.

10. The inorganic solar cell of claim 1, wherein the inorganic semi-conducting material is selected from a group consisting of amorphous silicon, copper indium gallium selenide, microcrystalline silicone, and nanocrystalline silicon.

11. A method of forming an inorganic solar cell, comprising:
depositing an intrinsic layer on a patterned p-type material layer formed of inorganic semi-conducting material, the patterned p-type material layer having a first set of protrusions and a first set of recessions; and,
depositing an n-type material layer on the intrinsic layer,
wherein thickness of the intrinsic layer is configured to be less than magnitude of diffusion length for the inorganic semi-conducting material.

12. The method of claim 11, further comprising:
depositing p-type material on an electrode layer;
positioning an imprint lithography template in superimposition with the p-type material and reducing a distance between the template and the electrode layer such that p-type material fills a volume between the template and the electrode layer; and,
solidifying the p-type material forming the patterned p-type material layer having the first set of protrusions and the first set of recessions.

13. The method of claim 11, further comprising:
depositing p-type material on a patterned electrode layer by conformal deposition forming the patterned p-type material layer, the patterned electrode layer having a second set of protrusions and a second set of recessions.

14. The method of claim 13, further comprising:
depositing an organic monomer material layer on an electrode layer, the organic monomer material layer having a series of gaps sized and configured to provide exposed portions of the electrode layer;
exposing the organic monomer material layer and the exposed portions of the electrode layer to an etchant forming the second set of protrusions and the second set of recessions.

15. The method of claim 14, wherein the gaps are formed using an imprint lithography process.

16. The method of claim 14, wherein the gaps are formed by a break through etch process.

17. The method of claim 14, wherein the etchant is a weak acid.

18. The method of claim 14, wherein the second set of protrusions and the second set of recessions form concave arc-like structures in the electrode layer.

19. The method of claim 11, wherein at least one protrusion has a variable width providing a non-vertical wall angle.

20. A method of forming an inorganic solar cell, comprising:
depositing electrode material on a substrate;
etching the electrode material forming a patterned electrode layer having a plurality of protrusions and a plurality of recessions;
depositing a conformal layer of inorganic semi-conducting material on the electrode patterned electrode layer forming a patterned p-type material layer;
depositing an intrinsic layer on the patterned p-type material layer; and,
depositing an n-type material layer on the intrinsic layer.

21. The method of claim 20, wherein thickness of the intrinsic layer is less than diffusion length for the inorganic semi-conducting material.

22. An inorganic solar cell, comprising:
a patterned n-type material layer having a first set of protrusions and a first set of recessions;
an intrinsic layer positioned on the patterned n-type material layer; and,
a p-type material layer formed of inorganic semi-conducting material positioned on the intrinsic layer;
wherein thickness of the intrinsic layer is configured to be less than magnitude of diffusion length for the inorganic semi-conducting material.
